(19) United States
(12) Patent Application Publication
(10) Pub. No.: US 2009/0032393 A1
(43) Pub. Date: Feb. 5, 2009

(54) Mirror Magnetron Plasma Source

(75) Inventor: John Madocks, Tucson, AZ (US)

Correspondence Address: LAWRENCE R. OREMLAND, P.C., 5055 E. BROADWAY BLVD., SUITE C-214, TUCSON, AZ, 85711, US

(73) Assignee: General Plasma, Inc., Tucson, AZ (US)

(21) Appl. No.: 12/293,159

(22) PCT Filed: Mar. 16, 2007
(86) PCT No.: PCT/US07/06743

§ 371 Date: Sep. 16, 2008

Related U.S. Application Data
(60) Provisional application No. 60/783,680, filed on Mar. 17, 2006.

(51) Int. Cl. C23C 14/35

(52) U.S. Cl. 204/298.17

(57) ABSTRACT

A new and useful plasma source is provided, comprising at least one electrode connected to an alternating current power supply and disposed adjacent to a portion of a grounded substrate. The electrode has a center magnet that produces a magnetron plasma at the electrode when the electrode is biased negative by the alternating power supply, and a mirror plasma on the substrate when the electrode is biased positive by the alternating power supply.

### RELATED APPLICATION/CLAIM OF PRIORITY

This application is related to and claims priority from Provisional Application Ser. No. 60/783,680, Entitled Mirror Magnetron Plasma Source and filed Mar. 17, 2006, which provisional application is incorporated by reference herein.

### BACKGROUND AND SUMMARY OF THE INVENTION

The present invention relates to a new and useful plasma source for industrial applications. The plasma source comprises at least one electrode connected to an alternating current power supply and disposed adjacent to a portion of a grounded substrate. The electrode has a center magnet that produces a magnetron plasma at the electrode when the electrode is biased negative by the alternating power supply, and a mirror plasma on the substrate when the electrode is biased positive by the alternating power supply.

The grounded substrate is preferably positioned within 100 mm from the electrode, and even more preferably within 20-50 mm from the electrode.,

The mirror plasma on the substrate produces a high energy, high density ion bombardment of the substrate. The magnetron plasma on the alternating half of the power supply cycle provides neutralizing electrons to the substrate. The mirror plasma on the substrate is useful for rapid ion cleaning and surface treatment. Additionally, the present invention can be beneficially applied to plasma enhanced chemical vapor deposition and sputter deposition processes.

In one specific application of the principles of the present invention, the electrode and the center magnet are oriented such that the magnetron plasma is produced on the side of the electrode when the electrode is biased negative by the alternating power supply. In addition, the electrode is disposed in a containment structure that is configured to provide containment of plasma sustaining gas about the electrode and the portion of the substrate adjacent the electrode. Moreover, the plasma source is located in a vacuum chamber, and the containment structure that is located in the vacuum chamber and electrically isolates the electric field associated with the mirror plasma from the environment of the vacuum chamber.

Further features of the present invention will be apparent from the following detailed description and the accompanying drawings.

### BRIEF DESCRIPTION OF THE DRAWINGS

FIG. 1 shows a section view of a mirror magnetron plasma source (MMPS), according to the principles of the present invention;

FIG. 2 shows a top view the MMPS depicted in FIG. 1;

FIG. 3 shows a voltage vs. time graph exemplifying typical source operation;

FIG. 4 shows a schematic view of a mirror magnetron plasma source with a separate planar magnetron for neutralization, further according to the principles of the present invention; and

FIG. 5 shows a section view of another embodiment of an MMPS, according to the principles of the present invention.

### DETAILED DESCRIPTION

In its most basic aspect, a plasma source according to the present invention comprises at least one electrode connected to an alternating current power supply and disposed adjacent to a portion of a grounded substrate. The electrode has a center magnet that produces a magnetron plasma at the electrode when the electrode is biased negative by the alternating power supply, and a mirror plasma on the substrate when the electrode is biased positive by the alternating power supply.

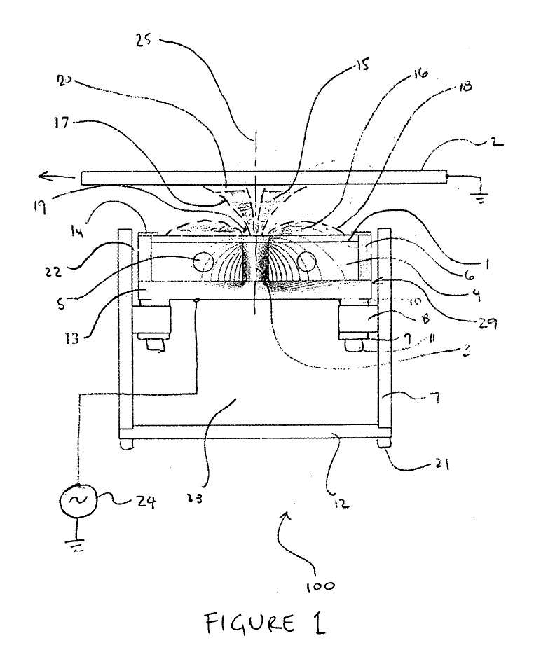

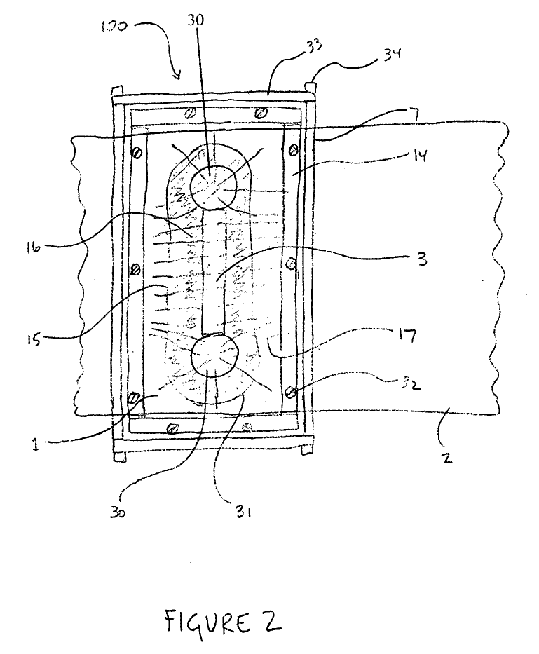

FIG. 1 is a section view of a linear mirror magnetron plasma source employing the inventive principles. FIG. 2 shows a top view of this source. Source 100 is positioned in a vacuum chamber not shown. Source 100 is comprised of an electrode 29 supported inside a floating outer box. The floating box is constructed from aluminum sides 7, bottom cover 12 and ends 33 (shown in FIG. 2). Electrode 29 includes water cooled core 4, magnet 3, shunt base 13, shunt sides 6, target 1 and target clamp plates 14. Core 4 is water cooled via passages 5 and connecting water lines not shown. Target 1 is clamped to core 4 by clamp plates 14 and fasteners 32 (FIG. 2). Core 4 is fastened inside shunt base 13 and shunt sides 6. Fasteners holding core 4 to shunt base 13 and shunt sides 6 to shunt base 13 are not shown. Shunt base 13 is supported inside the floating box by brackets 8 and insulating washers 9 and 10. Screw 11 is threaded into shunt base 13 and is electrically isolated by washers 9 and 10 from brackets 8. Brackets 8 are fastened to sides 7 by screws not shown.

In source 100 magnet 3 is made from a rare earth magnet material such as Neodymium Iron Boron. Magnet 3 must produce magnetic fields of sufficient strength to confine electrons both in a magnetron trap region 16 (by magnetic field lines 18) and a magnetic mirror trap region 15 (mirror region being bounded by field lines 17). For electrons to be confined in these traps the field lines in these regions must be generally in excess of 50 gauss. To give scale to the MMPS of FIG. 1, the magnet dimension is 19 mm high×13 mm wide. FIG. 1 is a section view. As will be described later, the MMPS can be extended to lengths exceeding 3 meters, similar to a planar magnetron cathode.

During operation the MMPS sustains both a magnetron electron trap and a mirror electron trap. Magnetron trap region 16 is well known in the art as a planar magnetron. Other configurations such as rotatable magnetrons and sputter guns are also well known in the art and the present invention can be built using these. The magnetron trap region 16 operates when target surface 1 is biased sufficiently negative to ignite and sustain a plasma. Electrons in the plasma are impeded from crossing magnetic field lines 18 and are repelled by the negative charge at target surface 1. As electrons move in response to the electric field, they are turned orthogonally to the magnetic and electric fields in the Hall current direction. When the magnetic field lines 18 are configured in an endless ‘racetrack’, the electrons are efficiently trapped close to target 1 to sustain a low voltage, low pressure discharge.

The magnetic mirror electron trap is also known in the art. Lamont Jr. in U.S. Pat. No. 4,673,480 implemented a mirror trap as a sputter source. Madocks in U.S. Pat. Nos. 6,911,779 and 7,023,128 and in patent application US20060152162A1. The U.S. Pat. No. 7,023,128 in particular has relevance to this application. In the present MMPS invention, a mirror electron trap is created between the substrate 2 and target 1. Magnet 3 produces a strong magnetic field at target source 1 (region 19) and the field grows weaker as the field lines emanate away from target 1. At substrate 2 the magnetic field of lines 17 are at least 2 times weaker than at target 1. When substrate 2 is positioned over source 100 at a distance of 2 or more centimeters, the gradient magnetic field can easily reach 10:1. To properly confine electrons in magnetic mirror trap region 15, field lines 17 must be at least 50 gauss in strength. This requirement limits the distance between substrate 2 and target 1. Also, field lines 17 bloom out from the centerline 25 as they return to the opposite magnet pole. Substrate 2 must be positioned close enough to source 100 so that field lines 17 pass into substrate 2. These requirements dictate that substrate 2 be positioned typically within 100 mm from target 1. A distance of 20 to 50 mm is preferred.

A mirror discharge in magnetic mirror trap region 15 is ignited and sustained when target 1 is biased positively with sufficient voltage. In this state, the grounded substrate 2 is relatively negative and becomes a ‘cathode’ to the positively charged target ‘anode’. As described in the earlier prior art work, the mirror discharge confinement operates at voltages higher than a magnetron. This is due to the imperfect electron confinement of the magnetic mirror and the loss of some high energy electrons to the anode. Electrons in the discharge attempting to reach target 1 are impeded by the gradient magnetic field

Electrode 29 is connected to alternating current power supply 24. In FIG. 1, source 100 is applied to a flat, conducting substrate 2 such as a metal sheet. Substrate 2 is grounded so that current can flow from the substrate to the power supply. Substrate 2 is moved relative to source 100 to treat substrate 2 uniformly.

Source 100 operation is initiated when sufficient gas pressure is present and power supply 24 is turned on. The process gas can be an inert gas such as argon, a reactive gas such as oxygen, a molecular gas such as methane or a combination of gases. The operating pressure range for the MMPS is generally from 1 millitorr to 60 millitorr. Power supply 24 is an alternating current power supply capable of delivering sufficient voltage to ignite the discharges and sufficient current for the process/application requirements. The frequency of power supply 24 can range from approximately 60 Hz to 13.56 MHz. Further discussion of power supply frequency considerations follows below.

During the first negative going cycle of power supply 24, electrode 29 becomes a cathode relative to ground. With sufficient voltage, a magnetron glow discharge in magnetron trap region 16 is ignited adjacent to target 1. This magnetron glow discharge in magnetron trap region 16, created by the electron trap of arching magnetic field lines 18 over target 1, is well known in the art. In this case an important attribute of the magnetron discharge in magnetron trap region 16 is the generation of electrons.

On the positive cycle of the AC power supply 24, magnetron plasma in region 16 extinguishes and electrode 29 becomes positively biased. When the positive bias of electrode 29 becomes sufficient, a mirror discharge in magnetic mirror trap region 15 ignites between grounded substrate 2 and electrode 29 confined between magnetic field lines 17. Magnetic mirror plasma confinement is known in prior art as referenced above. As described in these earlier references, a magnetic mirror plasma is sustained when the ratio of strong to weak field lines is greater than 2:1 and the expanded, weak field lines pass into an electron confining surface. In the case of source 100, the expanded, weaker magnetic field lines 17 pass into substrate 2. When electrode 29 is biased positively. Substrate 2 becomes relatively negative and electrons are repelled at the substrate 2 surface. As mirror plasma in magnetic mirror trap region 15 is established, a dark space forms at substrate 2. Another aspect of the mirror discharge in region 15 is confinement of the Hall current electron drift. As electrons oscillate between electrostatic confinement near substrate 2 and mirror confinement toward region 19, they experience a sideways drift due to orthogonal electric fields and gradient magnetic fields. By arranging the source 100 parallel to substrate 2, field lines 17 form an endless oval on substrate 2 over target 1, and the mirror confinement region bounded by field lines 17 forms a closed drift electron racetrack. In the case of source 100 and substrate 2, this is accomplished naturally by a single row of magnets 3 down the center of a linear source 100 (FIG. 2). The magnetic field 17 emanating out of target 1 passes into substrate 2 to form a fully enclosed hall current racetrack mirror discharge in mirror magnetic trap region 15. Substrate 2 must be large enough to block field lines 17 around the full racetrack. If this is not the case, the mirror discharge impedance will be much greater and source 100 operation will be detrimentally effected. FIG. 2 shows a better view of the substrate over source 100.

After ignition, a conductive mirror plasma in mirror magnetic trap region 15 is sustained. Visually this is seen as a glow discharge in region 15 with a dark space 20 adjacent to substrate 2. During the sustained mirror glow period in region 15 (on the positive side of the AC waveform) the substrate receives a dense ion bombardment from ions emanating out of plasma in region 15 across dark space 20.

On the following negative cycle of the power supply 24, electrode 29 once again becomes a cathode and magnetron plasma in magnetron trap region 16 ignites. This AC negative-positive cycle repeats with the alternating magnetron and mirror plasma discharges in operation. It is in this repeating cycle of alternating discharges that the advantage of the inventive method is manifest. During the positive cycle, ions emanating from mirror glow in mirror magnetic trap region 15 bombard substrate 2. On the negative cycle electrons are emitted from magnetron glow in magnetron trap region 16. The result is grounded substrate 2 is subjected to an intense, and neutralized, ion and plasma bombardment.

FIG. 2 shows a top view of the FIG. 1 source. In this view clamp plates 14 are shown around target 1 with fasteners 32 securing target 1 to electrode 29. Floating box sides 7 and ends 33 enclose electrode 29. Sides 7 are fastened to ends 33 by fasteners 34. Substrate 2 is shown as transparent so source 100 can be seen below it. For clarity, the magnets below target 1 are shown. The magnet assembly is composed of center magnet 3 and end magnets 30. End magnets 30 are larger than center magnets 3 to provide additional coercive force emanating at the ends. This helps to keep the magnetic field at the racetrack ends strong given the added area of the turnarounds. Source 100 is depicted in operation in FIG. 2. Magnetic field lines 17 are depicted as they radiate out from the magnets below target 1 toward substrate 2. The magnetron glow in magnetron trap region 16 is depicted as a shaded dog boned region on target 1. Mirror glow in magnetic mirror trap region 15 is a hatched region surrounded by an oval line. Note that substrate 2 is wider than the mirror glow outline in region 15. This insures that electrons are confined electrostatically by the grounded substrate 2 as they move along magnetic field line 17. (Magnetic field lines 17 are only roughly depicted to indicate the general shape of the confined magnetic mirror trap region 15.)

FIG. 2 shows source 100 as it appears in operation. With power supply 24 frequencies in the range of 40 to 450 kHz, the magnetron discharge 10 and external mirror discharge in region 15 appear as continuous plasma glows.

Source 100 shown in FIG. 2 can be extended linearly to lengths exceeding 3 meters. This is similar to a planar or rotatable magnetron cathode. The result is a uniform, high energy plasma and ion source for treating, sputtering and/or ion bombarding a large area substrate.

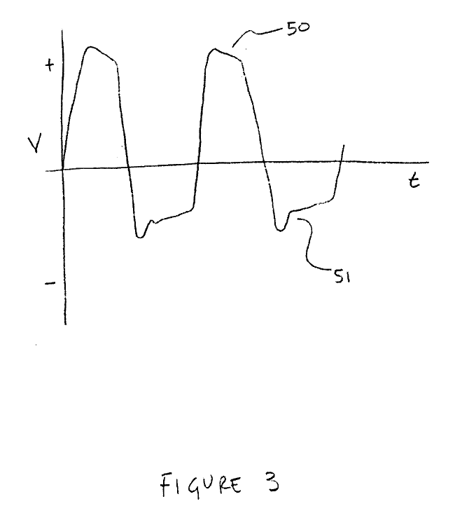

FIG. 3 depicts a voltage waveform of typical source operation. The voltage waveform was measured at the output of power supply 24 connected to the source 100 as shown in FIG. 1. The frequency of power supply 24 was 100 kHz. As shown in FIG. 3, the positive portion 50 of the alternating cycle rises to the ignition voltage of the mirror discharge in region 15. This is typically between 400 and 1000V. During this test the peak voltage 50 was approximately 525V. On the negative portion 51 of the AC cycle the source voltage drops until magnetron discharge in magnetron trap region 16 ignites. As has been described in the prior art referenced earlier, the voltage of the mirror discharge in region 15 is typically higher than a magnetron discharge in region 16. This is due to the loss of some high energy electrons through the mirror. In the case of the present invention, this higher voltage is an advantage because the higher voltage of the mirror discharge produces a higher ion energy impinging on substrate 2.

Several factors affect mirror discharge ignition and sustaining voltages. These factors include: the substrate 2 material, the process gas 6, the process gas flow and the process chamber pressure. Substrate 2 material is an important consideration because both secondary electron emission characteristics and sputter yield effect source operation.

As can be seen in FIG. 3 and is mentioned above, the magnetron discharge in region 16 on the negative side of the waveform has a lower voltage than the positive mirror discharge. While a lower magnetron voltage is typical, this is not mandatory for the inventive method and several factors can raise, or lower, the magnetron discharge voltage. For instance the target 1 material choice will affect the discharge voltage as will the gas type 6, gas flow and overall pressure.

The frequency of power supply 24 also effects the operation of source 100. As stated earlier, the frequency of discharge power supply 24 can range from 60 Hz to 13.56 MHz and beyond. Though the basic operating principle of alternating magnetron and mirror discharges remains the same, the frequency can be important. For instance, in the case of an insulating substrate such as a flexible polymer web material, the power supply frequency must be high enough to minimize charging effects. When a grounded, conductive substrate is used, such as a metal strip, the frequency can be lower. For insulating thin substrate materials, the power supply 24 frequency should be in the range of 40 kHz-13.56 MHz to keep substrate charge build up to within an acceptable level. For a grounded substrate, the power supply 24 frequency can range from 60 Hz to 13.56 MHz. Power supplies with output frequencies in the range of 40 kHz to 450 kHz are a good choice because they are readily available even at high powers, electrical noise issues are minimal and the voltage output can be converted using simple transformer type load match circuits. Another aspect of power supply frequency relates to ion motion. As the frequency is raised above 1 MHz, ions may not be accelerated out of the source before the cycle changes from positive to negative. In this case the ion energy may be lower due to multiple acceleration steps.

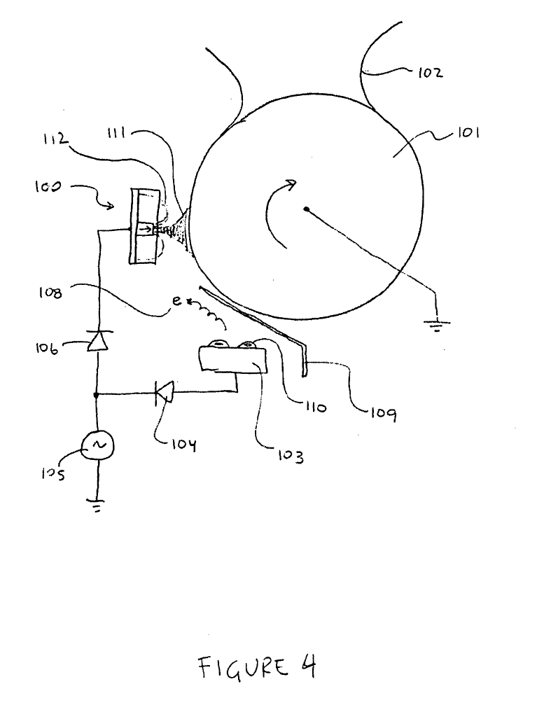

FIG. 4 shows a schematic view of another preferred embodiment. This embodiment is intended to not only present another useful configuration of the present invention but to illustrate the broad range of configurations within the scope of the invention. In FIG. 4, source 100 is positioned over substrate 102. Drum 101 supports a polymer web substrate 102 and drum 101 turns to continuously move substrate 102 past source 100. Web 102 and drum 101 are located in a vacuum chamber not shown. Drum 101 is grounded. Source 100 is similar to source 100 in FIGS. 1 and 2. Source 100 produces a mirror discharge 111 with substrate 101 and drum 102 as shown. Source 100 is connected to power supply 105 through diode 106. The same pole of power supply 105 is also connected to a separate planar magnetron 103 through diode 104. The opposed pole of power supply 105 is connected to ground. Source 100 is a long, linear source to uniformly treat web substrate 102. Planar magnetron 103 can be either long or short and is used only to provide neutralizing electrons to mirror discharge 111.

In operation gas is delivered near source 100 and planar magnetron 103 to produce a pressure in the range of 0.5 to 50 millitorr. Power supply 105 is turned on. With this embodiment diodes 106 and 104 control the operation of the two sources. During the negative power supply 105 cycle, planar magnetron 103 ignites and operates to flow ions (holes) though diode 104 to power supply 105. Electrons emanate out from planar magnetron 103 into the process chamber. During the negative cycle, source 100 is not active as diode 106 blocks current flow. On the positive cycle, planar magnetron cathode discharge 110 shuts off and diode 104 blocks current flow. On this positive cycle, diode 106 allows current flow to source 100. This allows mirror discharge 111 to ignite per the inventive method. Ions are emitted during this positive cycle from source 100 and these ions impinge on substrate 102, treating the substrate. As can be seen, the functions of ion emission and neutralizing electron emission have been separated into two sources. While this may add complexity, this configuration has advantages. One advantage is the sputter flux from magnetron 103 is blocked from reaching substrate 102. This is accomplished by placing shield 109 in front of sputter magnetron 103.

Note that substrate 102 is a polymer, insulating material that is supported by the grounded drum 101. Therefore, as described above, power supply 105 frequency must be high enough to capacitively coupled current through web 102 to drum 101. Also note that in the FIG. 4 configuration, the magnetron glow 16 of source 100 does not light. This is because diode 106 prevents current flow during the negative AC cycle to source 100.

It is important to note that MMPS operation is detrimentally affected if an electron emitter is proximal and active during the mirror discharge cycle. For instance, if a second planar magnetron is operating near source 100 in a constant DC mode then this cathode would be supplying electrons to the system constantly and source 100 would not operate properly. The positive voltage needed to ignite mirror discharge 111 is relatively high. If electrons are available in the process chamber near source 100 they will be attracted to the positive bias of source 100 (on the positive AC cycle) and they will keep the power supply voltage from rising high enough to light the mirror discharge 111. To prevent this problem source 100 must be operated without an electron source present during the positive cycle. This is accomplished by separating source 107 from other electron sources or by shielding source 107. Other examples of electron sources that can cause problems during operation include thermionic filaments, electron beam sources and hollow cathodes.

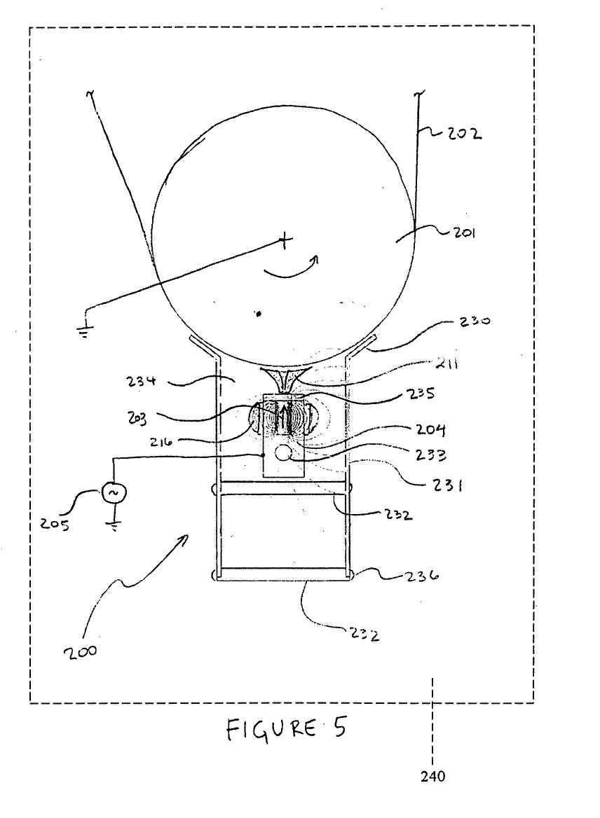

FIG. 5 shows a section view of another MMPS embodiment. This source 200 can be extended to long lengths to treat wide substrates. Source 200 has a center bar electrode 204 of aluminum or other non-magnetic material with a groove in the center to house magnet 203. Cover 235 protects center bar electrode 204 and magnet 203 from minor plasma 211. Fasteners attaching cover 235 to bar 204 are not shown. Center bar electrode 204 has a gun drilled hole 233 for water cooling. Water cooling piping is not shown and is well known in the art. Bar 204 is supported inside box 231 by insulating fasteners not shown. Box 231 has bottom support plates 232 attached by fasteners 236. Box 231 fits closely to roller 201 with approximately a 1 mm gap between the roller and box sealing edges 230. Web substrate 202 is supported by roller 201. Roller 201 is grounded. Web 202 is relatively thin, on the order of less than 200 microns so it does not interfere with box edges 230. Power supply 205 is connected to center bar electrode 204. Power supply 205 is a mid frequency power supply with a frequency of 100 kHz-13.56 MHz. Process gas is delivered into box cavity 234 through a fitting not shown. The source 200 and box 230 are located in a vacuum chamber (shown schematically at 240)

In operation gas is delivered into cavity 234 and power supply 205 is turned on. With sufficient pressure and voltage, twin glows light around center bar electrode 204 per the inventive method. One glow is a magnetron plasma 216. This lights during the negative cycle of the AC power supply 205. Mirror glow 211 lights on the positive power supply cycle. The embodiment of FIG. 5 has the advantage that less sputtered material from center bar electrode 204 is deposited on substrate 202. Also, this configuration is small in size so it can fit in small spaces.

Box 231 with edges 230 seals around roller 201 and serves two purposes: One, it helps to create a local gas containment cavity to maintain a specific gas adjacent to the working plasmas 216 and 211. For instance oxygen gas can be delivered into cavity 234 and the sealed nature of the cavity will help to keep the oxygen gas concentration high. This is important in large vacuum chambers with different processes operating simultaneously. Secondly, the box keeps center bar electrode 204 from lighting other plasmas during the positive cycle. As has been explained above, a nearby hollow cathode can light before the mirror plasma 211 and this will stop plasma 211 from lighting. The box 231 tends to keep the electric field within cavity 234 and helps to guarantee that the mirror plasma 211 will light properly.

The present invention has benefits and features important to several processes and applications:
A dense plasma is sustained over a substrate with a high plasma potential relative to the grounded substrate. This results in a large, high energy ion flux impinging on the substrate. Using readily available mid-frequency power generators, ion currents in the 10's or even 100's of amps can be directed onto the substrate. This dense, high energy ion flux can clean and modify the surface of a substrate quickly. For instance, in aluminum metalizing of plastic webs line speeds can exceed 10 m/s. To effectively treat the web before aluminum deposition, very high ion energies and densities are required.
The present invention can be made into long, linear sources capable of uniformly treating large area substrates. Uniform treatment is critical for successful large area thin film processes.
Unlike several other ion sources, separate electron neutralizer sources are not needed. Typical high density ion sources like End hall sources require a separate electron neutralizer like a filament or a hollow cathode heated source. The MMPS uses the action of the magnetron discharge on the negative cycle to produce a uniform, neutralizing source of electrons. This is seen in operation when no arcing or sparking is seen in the vacuum chamber. As is known in the art, when a charge imbalance is experienced, sparking will be visible on the substrate or chamber walls. The self neutralizing capability of the present invention is especially important for long linear sources. In this case, the internal magnetron electron emitter provides a long, uniform source of electrons over the length of the source.
A single power supply is needed for source operation. This is an important benefit for low initial and operating costs and simplified operation. The one AC power supply drives the mirror discharge for ion generation and the magnetron discharge for electron neutralization.

The present invention can be applied to a number of thin film processes:
Sputtering can also be accomplished with the MMPS by encouraging the sputter aspect of magnetron discharge 100. The advantages of the MMPS are that the mirror discharge helps to increase the sputtered coating density on the substrate and insulating reactive coatings can be deposited without target charging or ‘disappearing’ anode problems. The sputtered coatings are dense because the mirror discharge, alternating with the magnetron discharge delivers impinging ions to the growing film. Reactive coatings such as aluminum oxide, titanium oxide and silicon oxide can be deposited with a stability similar to a dual magnetron arrangement. With the MMPS, AC operation avoids target charge buildup and the grounded substrate acts as a stable ground. When the substrate is a polymer web on a grounded drum or roll, the substrate covers the drum from coating preserving the quality of the ground. When the substrata is a metal surface the constantly replaced substrate surface acts to maintain a constant impedance return path to the power supply. Note that the high ion flux to the substrate during the mirror discharge will raise the re-sputter rate. However, the resulting sputtered films made by the MMPS will be very dense.
The high ion bombardment on the substrate can be effectively used for a plasma enhance chemical vapor deposition process. For instance, a diamond like coating (DLC) process requires high ion bombardment. In most prior art this is accomplished by biasing the substrate. With the MMPS, the needed high ion bombardment is created though the substrate is at ground potential. Also, unlike prior art ion source DLC processes, large area substrates can be effectively coated.

While two embodiments of the invention have been shown herein, several modifications can be made within the spirit of the invention. Possible modifications would include:
The powered electrode can be configured as a rotating magnetron.
Outer magnets can be implemented in addition to the center magnets. The center magnets must be stronger to produce the center mirror confinement on the substrate.

1. A plasma source comprising at least one electrode connected to an alternating current power supply and disposed adjacent to a portion of a grounded substrate; wherein the electrode has a center magnet that produces a magnetron plasma at the electrode when the electrode is biased negative by the alternating power supply, and a mirror plasma on the substrate when the electrode is biased positive by the alternating power supply.

2. A plasma source as defined in claim 1, wherein the substrate is positioned within 100 mm from the electrode.

3. A plasma source as defined in claim 1, wherein the substrate is positioned within a distance of 20-50 mm from the electrode.

4. A plasma source as defined in claim 1, further including a separate magnetron electrode electrically connected to the alternating power supply; the electrical connections between the alternating power supply, the electrode and the magnetron electrode (i) allowing current flow from the alternating power supply to the magnetron electrode during the negative cycle of the alternating power supply, and (ii) allowing current flow from the alternating power supply to the electrode disposed adjacent the portion of the grounded substrate during the positive cycle of the alternating power supply.

5. A plasma source as defined in claim 1, wherein the electrode and the center magnet are oriented such that the magnetron confinement is produced on the side of the electrode when the electrode is biased negative by the alternating power supply.

6. A plasma source as defined in claim 1, wherein the electrode is disposed in a containment structure that is configured to provide containment of plasma sustaining gas about the electrode and the portion of the substrate adjacent the electrode.

7. A plasma source as defined in claim 1, wherein the plasma source is located in a vacuum chamber and the electrode is disposed in a containment structure that is located in the vacuum chamber and electrically isolates the electric field associated with the mirror confinement from the environment of the vacuum chamber.
